(19) United States
(12) Patent Application Publication
(10) Pub. No.: US 2011/0267743 A1
(43) Pub. Date: Nov. 3, 2011

(54) SLIDING APPARATUS FOR ELECTRONIC DEVICE

(75) Inventor: WEN-BIN SHEN, Tu-Cheng (TW)

(73) Assignee: HON HAI PRECISION INDUSTRY CO., LTD., Tu-Cheng (TW)

(21) Appl. No.: 12/837,676

(22) Filed: Jul. 16, 2010

(30) Foreign Application Priority Data
Apr. 30, 2010 (TW) 99207912

(51) Int. Cl. H05K 7/00; F16C 29/02

(52) U.S. Cl. 361/679.01; 384/26

(57) ABSTRACT

A sliding apparatus includes a first sliding member and a second sliding member slidable relative to the first sliding member. Two sliding rails are attached to opposite sides of the first sliding member, each of the sliding rails defining an arc-shaped channel along a longitudinal direction of the sliding rail. The second sliding member includes two substantially parallel and substantially arc-shaped sliding portions formed at two opposite sides to be slidably received in the channels of the sliding rails.

### BACKGROUND

1. Technical Field

The present disclosure relates to sliding apparatuses and, particularly to a sliding apparatus used for an electronic device having a slidable display.

2. Description of Related Art

Usually, displays of electronic devices are slidable and rotatable for convenient operation. For example, a mobile phone generally has a main body and a slidable display mounted to the main body with a sliding apparatus. The display slides to a predetermined position substantially parallel to the main body, and then rotates to incline relative to the main body, for users to conveniently view the display. However, it is often very taxing to operate the display of the electronic device.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of a sliding apparatus.

FIG. 2 is an assembled, isometric view of the sliding apparatus of FIG. 1.

FIG. 3 is a top plan view of the sliding apparatus of FIG. 2.

FIG. 4 is a cross-sectional view of the sliding apparatus of FIG. 2, taken along line IV-IV.

FIG. 5 is an assembled view of the sliding apparatus of FIG. 2, showing the sliding apparatus in an operating state.

FIG. 6 is a cross-sectional view of the sliding apparatus of FIG. 5, taken along line VI-VI.

FIG. 7 is a sketch view of an electronic device using the sliding apparatus.

### DETAILED DESCRIPTION

The disclosure, including the accompanying drawings in which like references indicate similar elements, is illustrated by way of examples and not by way of limitation. It should be noted that references to “an” or “one” embodiment in this disclosure are not necessarily to the same embodiment, and such references mean at least one.

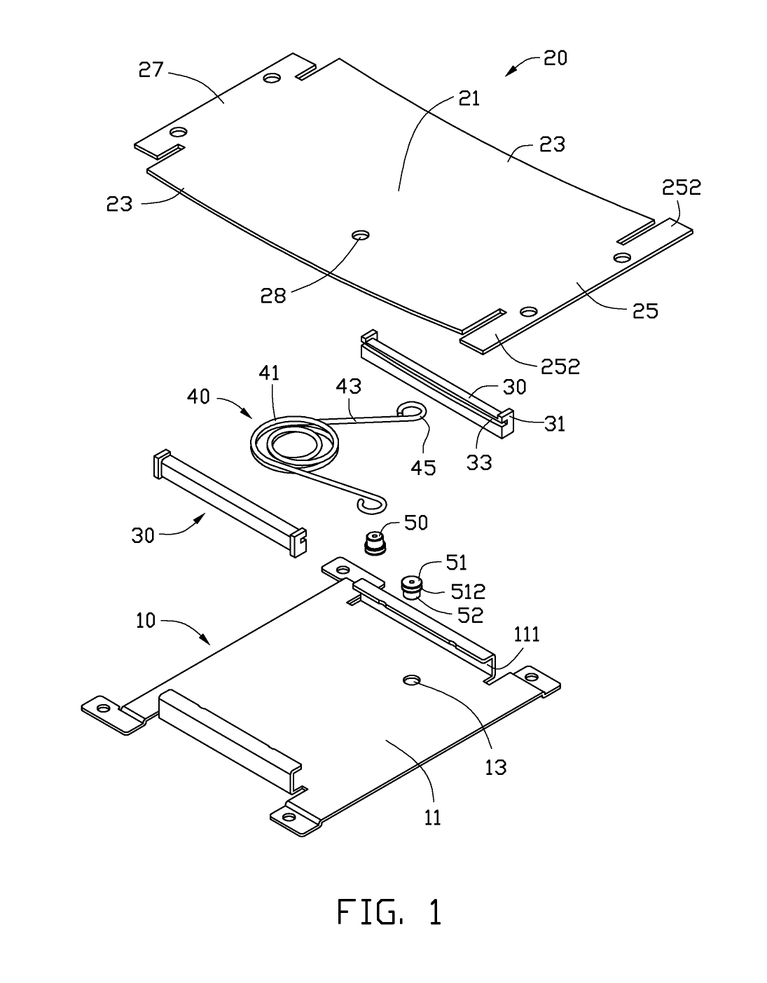

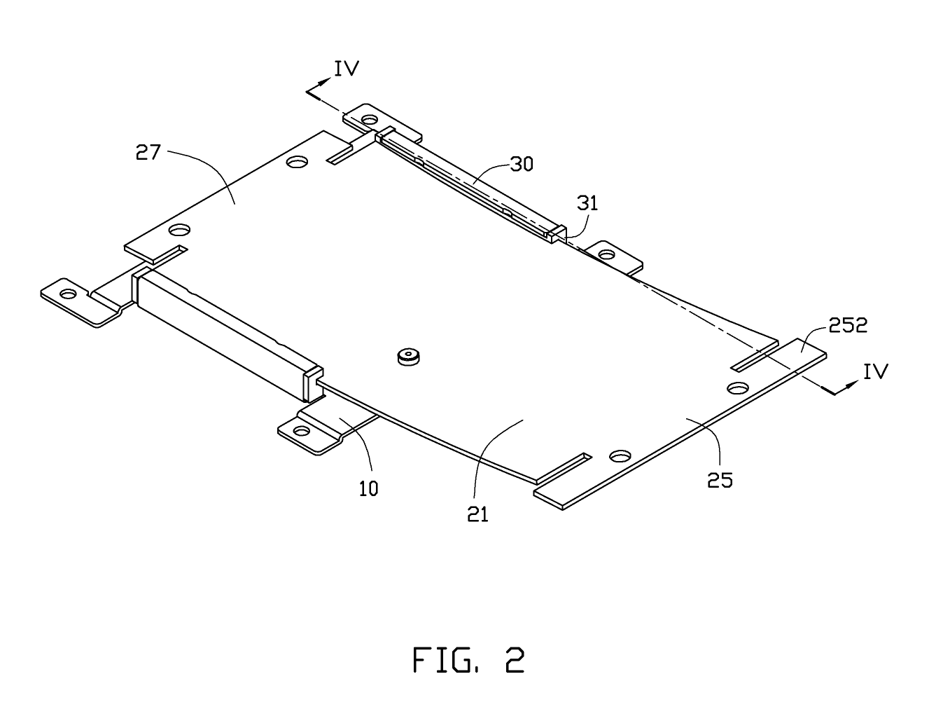

Referring to FIGS. 1 and 2, an embodiment of a sliding apparatus includes a first sliding member 10, a second sliding member 20, two sliding rails 30, a resilient member 40, and two positioning assemblies 50.

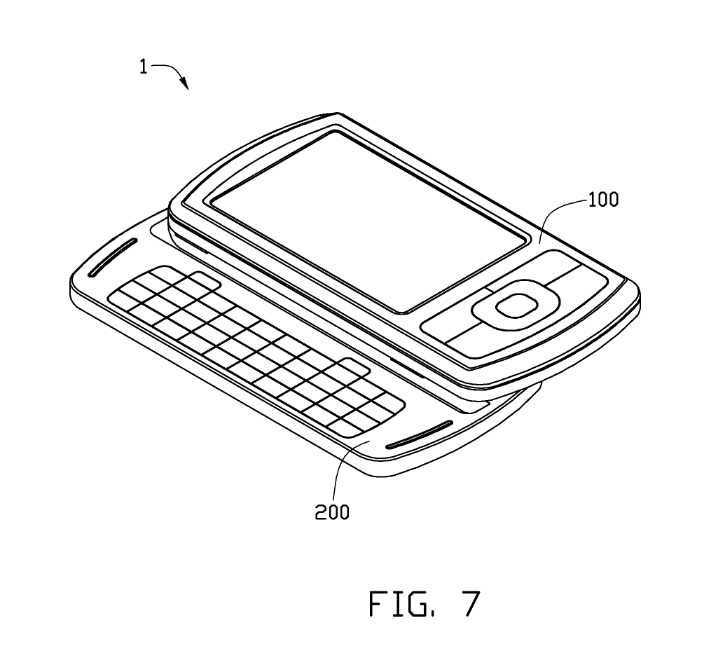

The first sliding member 10 includes a main body 11, each end of which is deformed to substantially encase a receiving portion 111 which has a substantially C-shaped cross-section. An opening is formed between each receiving portion 111 and the main body 11. The main body 11 defines a screw hole 13. The main body 11 defines four mounting holes at four corners, for fixing the first sliding member 10 to a base 200 of an electronic device 1, as shown in FIG. 7.

The second sliding member 20 is generally an arc-shaped plate, and includes a main plate 21, and a first mounting plate 25 and a second mounting plate 27 formed from opposite ends of the main plate 21. The main plate 21 forms two substantially parallel and substantially arc-shaped sliding portions 23 at two opposite sides. The width of the first mounting plate 25 is wider than that of the main plate 21. Two limiting portions 252 are formed from opposite ends of the first mounting plate 25. The width of the second mounting plate 25 is narrower than that of the main plate 21. A fixing hole 28 is defined in the main plate 21. The first mounting plate 25 and the second mounting plate 27 define a plurality of mounting holes for fixing the second sliding member 20 to a display 100 of the electronic device 1, as shown in FIG. 7.

Each end of each sliding rail 30 forms a limiting block 31. Each of the sliding rails 30 defines a substantially arc-shaped channel 33 along a longitudinal direction of the sliding rail 30. The channel 33 has a substantially U-shaped cross-section. Each of the sliding rails 30 is mounted in a corresponding receiving portion 111 through the opening of the main body 11. The limiting blocks 31 of each of the sliding rails 30 resist against two opposite ends of the corresponding receiving portion 111, to sandwich the receiving portion 111.

The resilient member 40 is a torsion spring and includes a coil portion 41 at a middle portion and two feet extending from opposite ends of the coil portion 41 respectively. Each foot includes a pole 43 and a substantially C-shaped clip 45 formed at a distal end of the pole 43.

In this embodiment, the fasteners 50 are rivets. Each fastener 50 includes a screw portion 52 and a locking portion 51 respectively formed at two opposite ends of the fastener 50. The locking portion 52 includes a column defining an annular recessed portion 512 in a circumference of the locking portion 52.

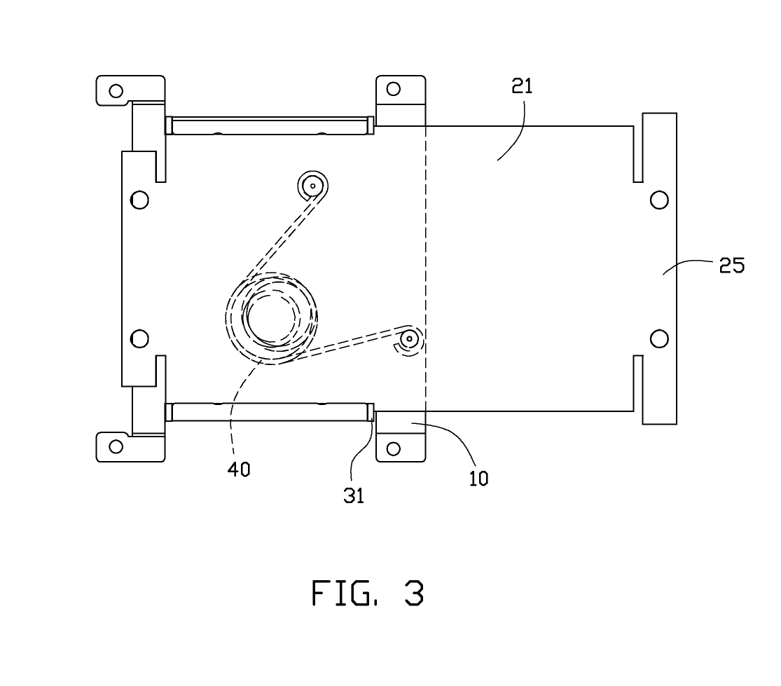

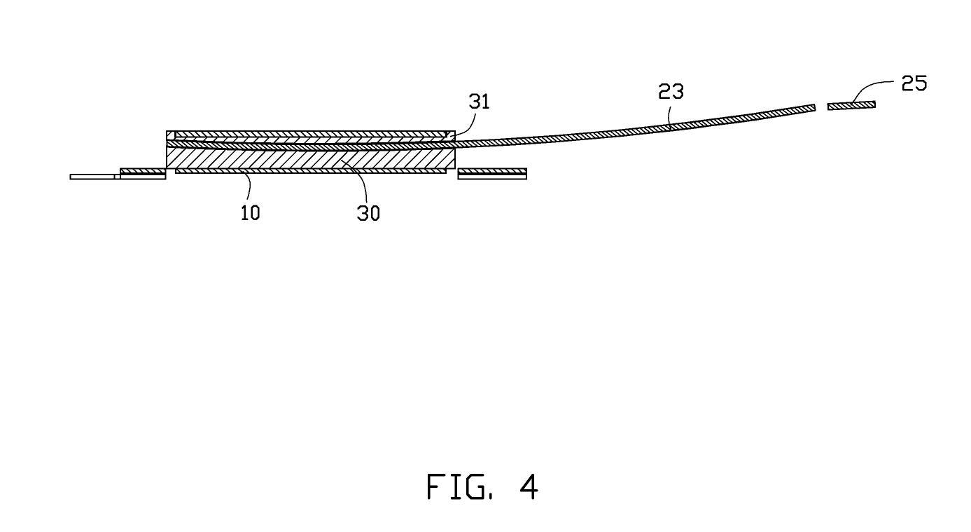

Referring FIGS. 3 and 4, in assembly, the sliding rails 30 are mounted in the corresponding receiving portions 111 of the first sliding member 10. The sliding portions 23 of the second sliding member 20 are slidably received in the corresponding channels 33 of the sliding rails 30 from the second mounting plate 27. The resilient member 40 is set between the first sliding member 10 and the second sliding member 20. The screw portions 52 of the fasteners 50 are respectively fixed in the screw holes 13 of the first sliding member 10 and the fixing holes 28 of the second sliding member 20. The clips 45 of the resilient member 40 are respectively positioned about the recessed portions 512 of the fasteners 50.

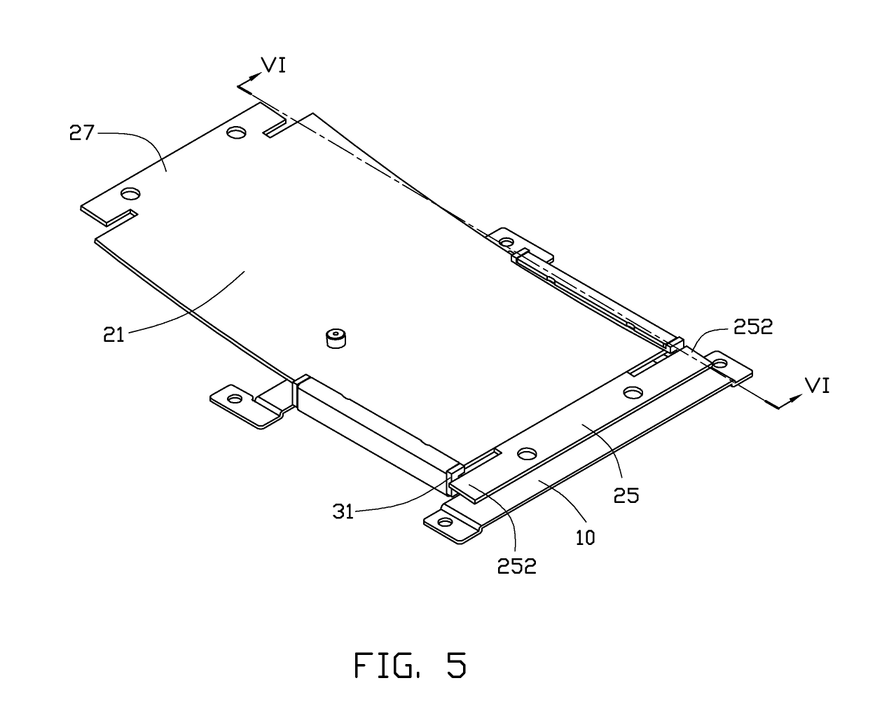

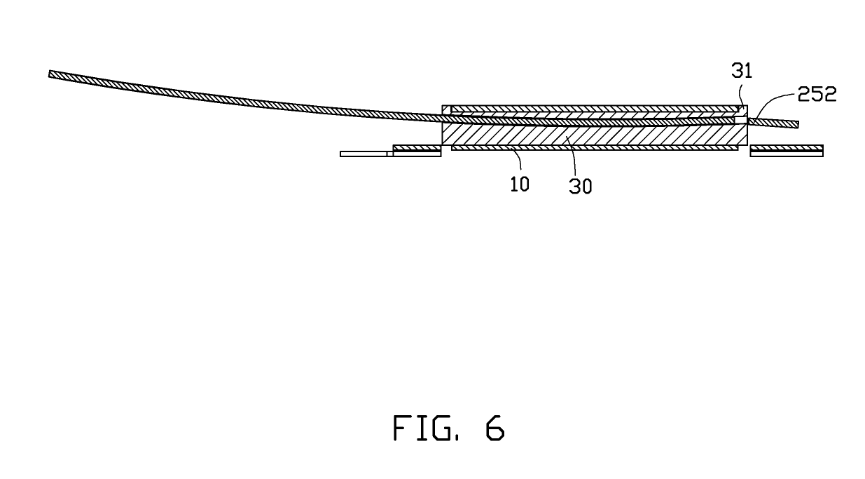

Referring to FIGS. 5 and 6, the sliding portions 23 of the second sliding member 20 slide in the channels 33 of the sliding rails 30 relative to the first sliding member 10, until the limiting portions 252 of the first mounting plate 25 of the second sliding member 20 engage with the limiting blocks 31 of the sliding rails 30. The second sliding member 20 slides in an arc.

Referring to FIG. 7, when the sliding apparatus is utilized in an electronic device 1, the first sliding member 10 and the second sliding member 20 are mounted respectively to a base 200 and a display 100 of the electronic device 1. The display 100 slides in an arc relative to the base 200 enabling an incline of the display 100 relative to the base 200, when the display 100 slides relative to the base 200, for users to conveniently view the display 100.

It is to be understood, however, that even though numerous characteristics and advantages of the embodiments have been set forth in the foregoing description, together with details of the structure and function of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A sliding apparatus comprising:
a first sliding member;
two sliding rails attached to opposite sides of the first sliding member, each of the sliding rails defining a substantially arc-shaped channel along a longitudinal direction of the sliding rail;
a second sliding member comprising two substantially parallel and substantially arc-shaped sliding portions formed at two opposite sides to be slidably received in the channels of the sliding rails; and
a resilient member connected between the first and second sliding members to restore the second sliding member to its original position.

2. The sliding apparatus of claim 1, wherein the first sliding member comprises a main body, each end of which is deformed to encase a receiving portion which has a substantially C-shaped cross-section, and each sliding rail is mounted in a corresponding receiving portion.

3. The sliding apparatus of claim 2, wherein two limiting blocks are formed at opposite ends of each of the sliding rails to resist against two opposite ends of the corresponding receiving portion, to sandwich the receiving portion.

4. The sliding apparatus of claim 1, wherein the second sliding member comprises a substantially arc-shaped main plate, and the sliding portions are formed at opposite sides of the main plate.

5. The sliding apparatus of claim 4, wherein the second sliding member comprises a first mounting plate formed at one end of the main plate, the width of the mounting plate is larger than that of the main plate, and two limiting portions are formed from opposite ends of the first mounting plate to engage with the sliding rails.

6. An electronic device comprising:
a base;
a first sliding member fixed to the base;
two sliding rails attached to opposite sides of the first sliding member, each of the sliding rails defining a substantially arc-shaped channel along a longitudinal direction of the sliding rail;
a display;
a second sliding member fixed to the display and comprising two substantially parallel and substantially arc-shaped sliding portions formed at two opposite sides to be slidably received in the channels of the sliding rails; and
a resilient member connected between the first and second sliding members to restore the second sliding member to its original position.

7. The electronic device of claim 6, wherein the first sliding member comprises a main body, each end of which is deformed to encase a receiving portion which has a substantially C-shaped cross-section, and each sliding rail is received in a corresponding receiving portion.

8. The electronic device of claim 7, wherein two limiting blocks are formed at opposite ends of each of the sliding rails to resist against two opposite ends of the corresponding receiving portion, to sandwich the receiving portion.

9. The electronic device of claim 6, wherein the second sliding member comprises a substantially arc-shaped main plate, and the sliding portions are formed at opposite sides of the main plate.

10. The electronic device of claim 9, wherein the second sliding member comprises a first mounting plate formed at one end of the main plate, the width of the first mounting plate is larger than that of the main plate, and two limiting portions are formed at opposite ends of the first mounting plate to engage with the sliding rails.

11. The electronic device of claim 10, wherein the second sliding member further comprises a second mounting plate formed from an opposite end of the main plate, the first and second mounting plates defining a plurality of mounting holes fixing the second sliding member to the display.
